(19) United States
(12) Patent Application Publication
(10) Pub. No.: US 2026/0198040 A1
(43) Pub. Date: Jul. 9, 2026

(54) SEMICONDUCTOR DEVICE INCLUDING TWO-DIMENSIONAL CHANNEL, METHOD OF MANUFACTURING SEMICONDUCTOR DEVICE, AND ELECTRONIC APPARATUS INCLUDING SEMICONDUCTOR DEVICE

(71) Applicant: Samsung Electronics Co., Ltd., Suwon-si (KR)

(72) Inventors: Hyeon Cheol PARK, Suwon-si (KR); Changhyun KIM, Suwon-si (KR); Baekwon PARK, Suwon-si (KR); Eunkyu LEE, Suwon-si (KR)

(73) Assignee: Samsung Electronics Co., Ltd., Suwon-si (KR)

(21) Appl. No.: 19/237,607

(22) Filed: Jun. 13, 2025

(30) Foreign Application Priority Data
Jan. 7, 2025 (KR) 10-2025-0002378

(51) Int. Cl. H10D 30/47; H10D 30/01

(52) U.S. Cl. CPC H10D 30/481; H10D 30/017

(57) ABSTRACT

A semiconductor device includes a channel layer, a gate electrode facing the channel layer, a gate insulating layer between the channel layer and the gate electrode, and a source electrode and a drain electrode electrically connected to the channel layer. The channel layer includes a semiconductor material having a two-dimensional crystal structure, and the gate insulating layer includes a three-dimensional bulk paraelectric material including zirconium oxide and an oxide of a metal having a valence of +3 or +4.

### CROSS-REFERENCE TO RELATED APPLICATION

This application is based on and claims priority under 35 U.S.C. § 119 to Korean Patent Application No. 10-2025-0002378, filed on Jan. 7, 2025, in the Korean Intellectual Property Office, the disclosure of which is incorporated by reference herein in its entirety.

### BACKGROUND

### 1. Field

The disclosure relates to a semiconductor device including a two-dimensional channel, a method of manufacturing the semiconductor device, and an electronic apparatus including the semiconductor device.

### 2. Description of the Related Art

Field effect transistors (FETs) are semiconductor devices that are configured to perform an electrical switching role and are used in various integrated circuit (IC) devices including memories, driving ICs, logic devices, and the like. With the increase in the degree of integration of an IC device, the space allocated for the occupation of an FET provided therein has rapidly reduced. Therefore, a reduction in the size of the FET is beneficial in meeting the increase in the degree of integration. However, FETs that include channels formed of silicon-based three-dimensional bulk materials have limitations in reducing the thickness and length thereof due to increased leakage current and increased resistance. Accordingly, attempts have been made to form channels of FETs by using two-dimensional materials instead of silicon-based three-dimensional bulk materials.

### SUMMARY

Provided are a semiconductor device using a two-dimensional material as a channel and an electronic apparatus including the semiconductor device.

Provided is a method of manufacturing the semiconductor device.

Additional aspects will be set forth in part in the description which follows and, in part, will be apparent from the description, or may be learned by practice of the presented embodiments of the disclosure.

According to an aspect of the disclosure, a semiconductor device includes a channel layer comprising a semiconductor material having a two-dimensional crystal structure, a source electrode electrically connected to the channel layer, a drain electrode electrically connected to the channel layer, a gate electrode facing the channel layer, and a gate insulating layer between the channel layer and the gate electrode, the gate insulating layer may include a three-dimensional bulk paraelectric material including zirconium oxide and an oxide of a metal having a valence of +3 or +4.

For example, the gate insulating layer may include Zr₍₁₋ₓ₎MₓO₂, wherein the M may be a metal having the valence of +3 or +4.

The M may include, for example, at least one of yttrium (Y), aluminum (Al), gallium (Ga), indium (In), silicon (Si), germanium (Ge), titanium (Ti), hafnium (Hf), tin (Sn), or a combination thereof.

In some examples, the x may be 0.01 to 0.3.

In some examples, the x may be 0.01 to 0.2.

The gate insulating layer may have a tetragonal crystal structure.

A thickness of the gate insulating layer may be 2 to 10 nm.

The semiconductor device may further include an intermediate insulating layer between the channel layer and the gate insulating layer, wherein the intermediate insulating layer may include at least one three-dimensional bulk paraelectric material, the at least one three-dimensional bulk paraelectric material including one or more of zirconium oxide, silicon oxide, titanium oxide, yttrium oxide, germanium oxide, tin oxide, aluminum oxide, indium oxide, hafnium oxide, gallium oxide, or a combination thereof.

A thickness of the intermediate insulating layer may be 0.1 nm to 2 nm.

The semiconductor material having the two-dimensional crystal structure may include a transition metal dichalcogenide material.

The semiconductor device may further include a substrate, wherein the channel layer may be on the substrate, the source electrode and the drain electrode may be respectively electrically connected to opposite ends of the channel layer, the gate insulating layer may be on the channel layer, and the gate electrode may be on the gate insulating layer.

The gate insulating layer may have at least one of a tetragonal crystal structure or an amorphous structure.

The gate insulating layer may be on an upper surface of the gate electrode, the channel layer may be on the gate insulating layer, and the source electrode and the drain electrode may be on the gate insulating layer and respectively electrically connected to opposite ends of the channel layer.

The semiconductor device may further include an upper gate insulating layer on the channel layer and an upper gate electrode on the upper gate insulating layer.

The gate insulating layer may have a tetragonal crystal structure, and the upper gate insulating layer may have at least one of a tetragonal crystal structure or an amorphous structure.

The semiconductor device may further include a substrate, wherein the channel layer may protrude from the substrate in a first direction, the gate insulating layer may surround an upper surface of the channel layer and opposite side surfaces of the channel layer in a second direction perpendicular to the first direction, and the gate electrode may surround an upper surface of the gate insulating layer and opposite side surfaces of the gate insulating layer in the second direction.

The semiconductor device may further include a substrate, wherein the channel layer may include a plurality of channel layers disposed at intervals from the substrate along a first direction, the gate insulating layer may include a plurality of gate insulating layers surrounding a lower surface and an upper surface of each of the plurality of channel layers and opposite side surfaces of each of the plurality of channel layers in a second direction perpendicular to the first direction, and the gate electrode may protrude from the substrate in the first direction so as to surround the plurality of gate insulating layers.

According to an aspect of the disclosure, a method of manufacturing a semiconductor device includes forming a channel layer including a semiconductor material having a two-dimensional crystal structure, forming a source electrode and a drain electrode so that the source electrode and the source drain are electrically connected to the channel layer, forming a gate insulating layer so that the gate insulating layer faces the channel layer, the gate insulating layer comprising a three-dimensional bulk paraelectric material comprising zirconium oxide and an oxide of a metal having a valence of +3 or +4, and forming a gate electrode on an area of the gate insulating layer such that the gate insulating layer is between the gate electrode and the channel layer, wherein the forming of the gate insulating layer includes depositing the gate insulating layer using atomic layer deposition and heat treating the deposited gate insulating layer at a temperature of 300° C. for 10 minutes or at a temperature of 400° C. for about 1 minute.

The depositing of the gate insulating layer may include depositing Zr₍₁₋ₓ₎MₓO₂ at a temperature of 150° C. to 200° C., and the M represents the metal having the valence of +3 or +4 and may include at least one of yttrium (Y), aluminum (Al), gallium (Ga), indium (In), silicon (Si), germanium (Ge), titanium (Ti), hafnium (Hf), tin (Sn), or a combination thereof.

According to an aspect of the disclosure, an electronic apparatus includes a transistor, a word line electrically connected to a gate of the transistor, a bit line electrically connected to a source of the transistor, and a capacitor electrically connected to a drain of the transistor, wherein the transistor includes a channel layer comprises a semiconductor material having a two-dimensional crystal structure, a source electrode electrically connected to the channel layer, a drain electrode electrically connected to the channel layer, a gate electrode facing the channel layer, a gate insulating layer between the channel layer and the gate electrode, the gate insulating layer includes a three-dimensional bulk paraelectric material including zirconium oxide and an oxide of a metal having a valence of +3 or +4.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view schematically illustrating a structure of a semiconductor device according to at least one example embodiment;

FIG. 2 is an X-ray diffraction (XRD) measurement result showing an example of crystal characteristics according to a heat treatment temperature of a material of a gate insulating layer in a semiconductor device according to at least one example embodiment;

FIG. 3 is a graph showing an example of a comparison of leakage current and equivalent oxide thickness characteristics of a semiconductor device according to various materials of a gate insulating layer;

FIG. 4 is a cross-sectional view schematically illustrating a structure of a semiconductor device according to at least one example embodiment;

FIG. 5 is a cross-sectional view schematically illustrating a structure of a semiconductor device according to at least one example embodiment;

FIG. 6 is a cross-sectional view schematically illustrating a structure of a semiconductor device according to at least one example embodiment;

FIG. 7 is a cross-sectional view schematically illustrating a structure of a semiconductor device according to at least one example embodiment;

FIG. 8 is a cross-sectional view schematically illustrating a structure of a semiconductor device according to at least one example embodiment;

FIGS. 9 to 11 are graphs showing an example of various performances of the semiconductor device illustrated in FIG. 7;

FIGS. 12 to 14 are graphs showing an example of various performances of the semiconductor device illustrated in FIG. 8;

FIG. 15 is a table showing an example of a comparison of various performances of semiconductor devices according to embodiments and various performances of a semiconductor device including a gate insulating layer using a material that is different from a material in the embodiments;

FIG. 16 is a perspective view schematically illustrating a structure of a semiconductor device according to at least one example embodiment;

FIG. 17 is a cross-sectional view schematically illustrating a channel layer and a gate electrode of the semiconductor device of FIG. 16 taken along line A-A′ of FIG. 16;

FIG. 18 is a cross-sectional view schematically illustrating a channel layer and a gate electrode of a semiconductor device according to at least one example embodiment;

FIG. 19 is a cross-sectional view schematically illustrating a channel layer and a gate electrode of a semiconductor device according to at least one example embodiment;

FIG. 20 is a circuit diagram of a complementary metal-oxide semiconductor (CMOS) inverter according to at least one example embodiment;

FIG. 21 is a circuit diagram of a CMOS static random access memory (SRAM) device according to at least one example embodiment;

FIG. 22 is a circuit diagram of a CMOS dynamic random access memory (DRAM) device according to at least one example embodiment;

FIG. 23 is a block diagram of an electronic apparatus according to at least one example embodiment; and

FIG. 24 is a block diagram of an electronic apparatus according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device including a two-dimensional channel, a method of manufacturing the semiconductor device, and an electronic apparatus including the semiconductor device are described in detail. In the following drawings, the size of each element in the drawings may be exaggerated for clarity and convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical and/or geometric values. In addition, embodiments described herein are merely examples, and various modifications may be made thereto from these embodiments.

Hereinafter, the terms “above,” “on,” “below,” or “under” may include not only those that are directly above, below, left, or right in a contact manner, but also those that are above, below, left, or right in a non-contact manner. Additionally, it will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. The singular forms as used herein are intended to include the plural forms as well unless the context clearly indicates otherwise. It will be understood that the terms “comprise,” “include,” or “have” as used herein specify the presence of stated elements, but do not preclude the presence or addition of one or more other elements.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

Also, the terms such as “unit” and “module” described in the specification mean units that process at least one function or operation, and may be implemented as processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Connecting lines or connecting members illustrated in the drawings are intended to represent exemplary functional relationships and/or physical or logical connections between the various elements. It should be noted that many alternative or additional functional relationships, physical connections or logical connections may be present in a practical device.

The use of all illustrations or illustrative terms in the embodiments is simply to describe the technical ideas in detail, and the scope of the disclosure is not limited by the illustrations or illustrative terms unless they are limited by claims.

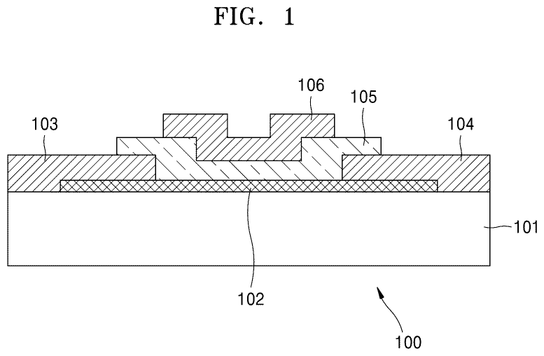

FIG. 1 is a cross-sectional view schematically illustrating a structure of a semiconductor device 100 according to at least one example embodiment. Referring to FIG. 1, the semiconductor device 100, according to at least one example embodiment, includes a channel layer 102, a source electrode 103 electrically connected to the channel layer 102, a drain electrode 104 electrically connected to the channel layer 102, a gate insulating layer 105 on the channel layer 102, and a gate electrode 106 on the gate insulating layer 105. The source electrode 103 and the drain electrode 104 may be spaced apart from each other and may be respectively electrically connected to opposite ends of the channel layer 102. In other words, the channel layer 102 may be provided between the source electrode 103 and the drain electrode 104 and configured to selectively electrically connect the source electrode 103 and the drain electrode 104. The gate electrode 106 may be provided to face the channel layer 102. The gate insulating layer 105 may be provided between the channel layer 102 and the gate electrode 106.

The semiconductor device 100 may further include a substrate 101. The substrate 101 may be an insulating substrate including, for example, at least one of glass, plastic, or dielectric. The channel layer 102, the source electrode 103, and the drain electrode 104 may be provided on the substrate 101. In at least some example embodiments, the source electrode 103 and the drain electrode 104 may be respectively in contact with opposite sides of the channel layer 102 on the substrate 101. For example, the source electrode 103 may be electrically connected to a first side surface of the channel layer 102, and the drain electrode 104 may be electrically connected to a second side surface of the channel layer 110 opposite to the first side surface of the channel layer 102.

The semiconductor device 100 may be, for example, a field effect transistor (FET). For example, in some example embodiments, the semiconductor device 100 may be an FET having a top gate structure in which the gate electrode 106 is disposed above the channel layer 102. In these cases, the gate electrode 106, the source electrode 103, and the drain electrode 104 may be provided on the same side with respect to the substrate 101. For example, the gate electrode 106, the source electrode 103, and the drain electrode 104 may all be provided to face the upper surface of the substrate 101.

The source electrode 103, the drain electrode 104, and the gate electrode 106 may include a conductive material, such as a zero-bandgap material (e.g., one or more of a metal, a conductive oxide, a conductive nitride, and/or the like) and/or a semiconductor material doped to have a conductivity substantially similar to the conductivity of a zero-bandgap material.

The channel layer 102 may include a semiconductor material having a two-dimensional (2D) crystal structure. A 2D structure may be in contrast to, e.g., zero-dimensional (0D) structures (e.g., quantum dots (QD)); one-dimensional (1D) structures (e.g., carbon nanotubes and/or a nanowire); and/or three-dimensional (3D) structures (e.g., structures having lattices including ionic and/or covalent bonds extending in three dimensions). For example, the channel layer 102 may include a transition metal dichalcogenide material. The transition metal dichalcogenide is a compound of a transition metal and a chalcogen element. In other words, the channel layer 102 may include MX₂, wherein M is a transition metal and X is a chalcogen element. The transition metal M may include at least one of molybdenum (Mo), tungsten (W), hafnium (Hf), zirconium (Zr), tantalum (Ta), titanium (Ti), rhenium (Re), niobium (Nb), tin (Sn), or platinum (Pt). The chalcogen element X may include at least one of sulfur(S), selenium (Se), or tellurium (Te). The channel layer 102 may include, for example, MoS₂, MoSe₂, MoTe₂, WS₂, WSe₂, TiS₂, ZrS₂, ZrSe₂, HfS₂, PtS₂, SnS₂, TaS₂, ReS₂, NbS₂, TaSe₂, HfSe₂, ReSe₂, TiSe₂, NbSe₂, SnSe₂, WTe₂, TaTe₂, HfTe₂, ReTe₂, TiTe₂, NbTe₂, SnTe₂, etc.

The transition metal dichalcogenide may have excellent electrical properties even at a relatively small thickness of, for example, 1 nanometers (nm) or less and a relatively small length of, for example, 5 nm or less, and the properties of the transition metal dichalcogenide may be easily controlled. Accordingly, when the channel layer 102 includes a transition metal dichalcogenide material, it may be advantageous for miniaturization of the semiconductor device 100 by overcoming the limitations of silicon (Si)-based semiconductors without significantly deteriorating the performance of the semiconductor device 100. According to at least one example embodiment, the channel layer 102 may be provided by stacking a transition metal dichalcogenide material having a two-dimensional crystal structure in one to ten layers or one to three layers. For example, the thickness of the channel layer 102 may be about 0.7 nm to about 7 nm, or about 0.7 nm to about 2.5 nm. For example, each of the layers constituting the channel layer 102 may form a crystal structure in a two-dimensional plane, and though the atoms comprising each layer may exist above and/or below the two-dimensional plane, the two-dimensional lattice of the 2D crystal structure may comprise vertices ordered in a single sheet. In some embodiments, the layers of the channel layer 102 may be coupled to each other through the van der Waals interactions and may lack dangling bonds extending in directions intersecting the two-dimensional plane. In some embodiments, the two-dimensional plane of the 2D material may be substantially parallel to the upper surface of the substrate 101. In addition, when the semiconductor device 100 includes the two-dimensional channel described above, the performance of the semiconductor device 100 may not be deteriorated even when the horizontal width or length of the gate electrode 106 is formed to be 10 nm or less.

In at least some embodiments, the channel layer 102 may be formed by growing transition metal dichalcogenide on a separate growth substrate and then transferring the grown transition metal dichalcogenide onto the upper surface of the substrate 101. For example, after the transition metal dichalcogenide is grown on the growth substrate by Chemical Vapor Deposition (CVD), Plasma Enhanced CVD (PE-CVD), Inductively Coupled Plasma Chemical Vapor Deposition (ICP-CVD), and/or the like, the grown transition metal dichalcogenide may be transferred onto the upper surface of the substrate 101. After that, the channel layer 102 may be formed by patterning the transition metal dichalcogenide transferred onto the upper surface of the substrate 101. Alternatively, the channel layer 102 may be formed by directly growing transition metal dichalcogenide on the substrate 101 and then patterning the transition metal dichalcogenide grown on the substrate 101.

The gate insulating layer 105 may include a three-dimensional bulk paraelectric material having relatively high dielectric constant characteristics of about 20 to about 40. In addition, the gate insulating layer 105 may include a three-dimensional bulk paraelectric material having a tetragonal crystal structure. For example, the three-dimensional bulk paraelectric material of the gate insulating layer 105 may include zirconium oxide (ZrO₂) and an oxide of a metal having a valence of +3 or +4. In other words, the gate insulating layer 105 may include Zr₍₁₋ₓ₎MₓO₂, wherein the metal M represents a metal having a valence of +3 or +4. For example, the metal M may include at least one of yttrium (Y), aluminum (Al), gallium (Ga), indium (In), silicon (Si), germanium (Ge), titanium (Ti), hafnium (Hf), tin (Sn), or a combination thereof. The thickness of the gate insulating layer 105 may be about 2 nm to about 10 nm.

Because zirconium oxide (ZrO₂) has slightly stronger covalent bonding properties than hafnium oxide (HfO₂), zirconium oxide (ZrO₂) has better interfacial bonding properties with transition metal dichalcogenide, such as MoS₂, having covalent bonding properties. More specifically, despite the lack of covalent bonds bonding the zirconium oxide to the transition metal dichalcogenide, an interfacial bond (e.g., a polar bond) between the gate insulating layer 105 and the channel layer 102 may be stronger when the gate insulating layer 105 includes zirconium oxide compared to when the gate insulating layer 105 includes hafnium oxide. Therefore, zirconium oxide (ZrO₂) may be formed relatively easily on the transition metal dichalcogenide, which is a two-dimensional material. In addition, because zirconium oxide (ZrO₂) reduces defects at the interface with the transition metal dichalcogenide, a defect-induced trap may be reduced. Accordingly, the performance of the semiconductor device 100 may be improved by reducing traps at the interface between the gate insulating layer 105 including the three-dimensional bulk paraelectric material and the channel layer 102 including the two-dimensional material. In addition, zirconium oxide (ZrO₂) may have a relatively high dielectric constant of about 47 when zirconium oxide (ZrO₂) has a tetragonal crystal structure. In general, in order to induce the tetragonal crystal structure, the zirconium oxide (ZrO₂) is heat-treated at a temperature of about 1,170° C. to about 2,370° C. At such relatively high temperatures, the condition of other components, such as the channel layer 102, may deteriorate, thereby potentially reducing the effectiveness of the semiconductor device 100.

According to at least one example embodiment, when Zr₍₁₋ₓ₎MₓO₂ used as the gate insulating layer 105 has a small thickness, Zr₍₁₋ₓ₎MₓO₂ may have a tetragonal crystal structure even when heat-treated at a relatively low temperature of about 300° C. or higher. For example, Zr(1-x)MxO2 may have a tetragonal crystal structure even when heat-treated at a temperature of about 300° C. to about 1000° C., about 300° C. to about 500° C., and/or about 300° C. to about 400° C. In Zr₍₁₋ₓ₎MₓO₂, the metal M may be selected from a metal having a valence of +3 or +4 so as not to lower the tetragonal crystallinity and dielectric constant of zirconium oxide (ZrO₂). In addition, the proportion of the metal M in Zr₍₁₋ₓ₎MₓO₂ may be significantly smaller than the proportion of zirconium (Zr). For example, x may be about 0.01 to about 0.3, about 0.01 to about 0.2, about 0.05 to about 0.3, about 0.05 to about 0.2, about 0.1 to about 0.3, or about 0.1 to about 0.2.

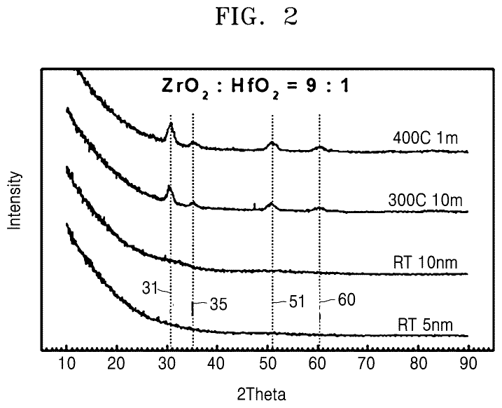

FIG. 2 is an X-ray diffraction (XRD) measurement result showing an example of crystal characteristics according to a heat treatment temperature of the material of the gate insulating layer 105 in the semiconductor device 100 according to at least one example embodiment. Zirconium oxide (ZrO₂) and hafnium oxide (HfO₂) were used as the gate insulating layer 105 at a ratio of 9:1 (e.g., x=0.1). Referring to FIG. 2, when the gate insulating layer 105 having a thickness of 5 nm and the gate insulating layer 105 having a thickness of 10 nm are heat-treated at room temperature, a peak indicating tetragonal crystallinity is not observed. However, when the gate insulating layer 105 having a thickness of 10 nm is heat-treated at a temperature of about 300° C. for 10 minutes and when the gate insulating layer 105 having a thickness of 10 nm is heat-treated at a temperature of about 400° C. for 1 minute, a peak indicating tetragonal crystallinity may be observed.

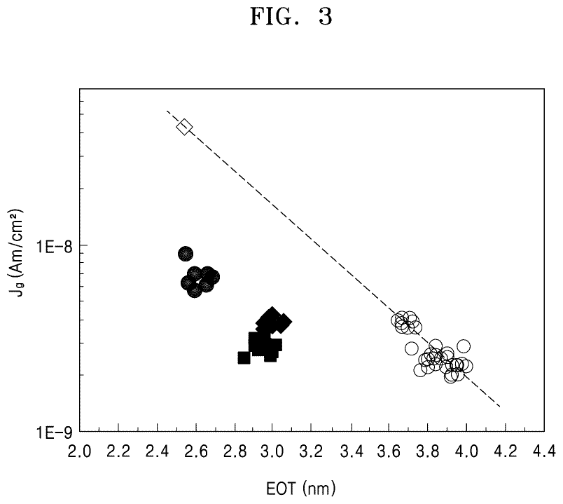

In addition, FIG. 3 is a graph showing an example of a comparison of leakage current and equivalent oxide thickness characteristics of the semiconductor device 100 according to various materials of the gate insulating layer 105. In FIG. 3, ‘○’ represents a characteristic when the gate insulating layer 105 includes only hafnium oxide (HfO₂) as a comparative example (i.e., x=1), ‘⋄’ represents a characteristic when the gate insulating layer 105 includes only zirconium oxide (ZrO₂) as another comparative example (i.e., x=0), ‘▪’ represents a characteristic when the gate insulating layer 105 includes zirconium oxide (ZrO₂) and hafnium oxide (HfO₂) at a ratio of 9:1 (i.e., x=0.1), ‘♦’ represents a characteristic when the gate insulating layer 105 includes zirconium oxide (ZrO₂) and hafnium oxide (HfO₂) at a ratio of 8:2 (i.e., x=0.2), and ‘●’ represents a characteristic when the gate insulating layer 105 includes zirconium oxide (ZrO₂) and aluminum oxide (Al₂O₃) at a ratio of 9:1 (i.e., x=0.1). A line segment indicated by a dashed line in FIG. 3 connects the comparative example of x=1 to the comparative example of x=0. On the other hand, the thickness of the gate insulating layer 105 was 10 nm, and MoS₂ was used as the channel layer 102.

Referring to FIG. 3, in the comparative example of x=0 including only zirconium oxide (ZrO₂), leakage current increases. In addition, in the comparative example of x=1 including only hafnium oxide (HfO₂), the equivalent oxide thickness increases. On the other hand, in the examples of x=0.1 or x=0.2, leakage current characteristics and equivalent oxide thickness characteristics may be lower than values on the line segment indicated by the dashed line. In other words, leakage current characteristics and equivalent oxide thickness characteristics in the examples appear on the lower left region of the line segment that connects the comparative example of x=1 to the comparative example of x=0. Therefore, the combined characteristics of the leakage current and the equivalent oxide thickness in the examples may be superior to those in the comparative examples.

As described above, in Zr₍₁₋ₓ₎MₓO₂, when the x value becomes excessively small, the equivalent oxide thickness may increase, and when the x value becomes excessively large, the leakage current may increase. In addition, when the x value becomes excessively large, the tetragonal crystallinity and dielectric constant properties of zirconium oxide (ZrO₂) may deteriorate. Considering this point, the lower limit of the x value may be about 0.01, about 0.05, or about 0.1 and the upper limit of the x value may be about 0.2 or about 0.3.

According to at least one example embodiment, the gate insulating layer 105 may be formed after the source electrode 103 and the drain electrode 104 are formed on the substrate 101 to be electrically connected to the channel layer 102. For example, the gate insulating layer 105 may be formed by depositing Zr₍₁₋ₓ₎MₓO₂ to cover the channel layer 102 by using atomic layer deposition (ALD) and then performing heat treatment on the deposited Zr₍₁₋ₓ₎MₓO₂. In the deposition process using the ALD, a deposition temperature may be about 150° C. to about 200° C. In the top gate structure illustrated in FIG. 1, in which the channel layer 102 is present under the gate insulating layer 105, Zr₍₁₋ₓ₎MₓO₂ may be deposited at a relatively low temperature of about 150° C. so as to prevent or reduce damage to the channel layer 102. However, in a bottom gate structure described below, Zr₍₁₋ₓ₎MₓO₂ may be deposited at a temperature of about 200° C. The heat treatment may be performed at a temperature of about 300° C. for about 10 minutes or at a temperature of about 400° C. for about 1 minute by using rapid thermal annealing (RTA).

After that, the gate insulating layer 105 may or may not be patterned when necessary. After the patterning, the gate insulating layer 105 may cover only the upper surface of the channel layer 102, or may remain in a partial area of the upper surfaces of the source electrode 103 and the drain electrode 104. After the gate insulating layer 105 is formed, the gate electrode 106 may be formed on an area of the upper surface of the gate insulating layer 105 which faces the channel layer 102.

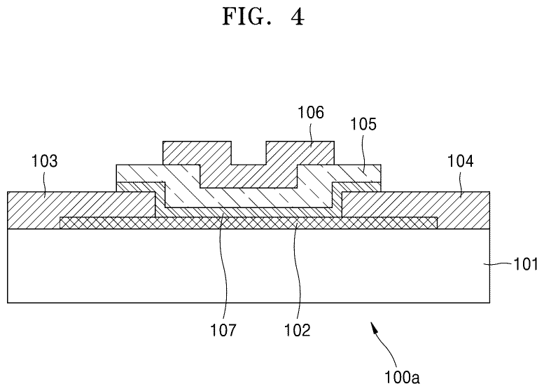

FIG. 4 is a cross-sectional view schematically illustrating a structure of a semiconductor device 100a according to at least one example embodiment. Referring to FIG. 4, the semiconductor device 100a according to at least one example embodiment may further include an intermediate insulating layer 107 between a channel layer 102 and a gate insulating layer 105. The remaining elements of the semiconductor device 100a illustrated in FIG. 4 may be the same as (or substantially similar to) those of the semiconductor device 100 illustrated in FIG. 1, and therefore repeat descriptions thereof may be omitted.

The intermediate insulating layer 107 may include a three-dimensional bulk paraelectric material that does not damage crystallinity of a gate insulating layer 105 while improving interfacial properties between the two-dimensional material of the channel layer 102 and the gate insulating layer 105. To this end, the intermediate insulating layer 107 may include an oxide of a metal having a valence of +3 or +4. The intermediate insulating layer 107 may include, for example, at least one three-dimensional bulk paraelectric material selected from zirconium oxide (ZrO₂), silicon oxide (SiO₂), titanium oxide (TiO₂), yttrium oxide (Y₂O₃), germanium oxide (GeO₂), tin oxide (SnO₂), aluminum oxide (Al₂O₃), indium oxide (In₂O₃), hafnium oxide (HfO₂), and gallium oxide (Ga₂O₃). The metal having a valence of +3 or +4 in the intermediate insulating layer 107 may be the same as or different to the metal (M) having a valence +3 or +4 in the gate insulating layer 105. This intermediate insulating layer 107 may be formed with a thickness less than a thickness of the gate insulating layer 105. For example, the thickness of the intermediate insulating layer 107 may be about 0.1 nm to about 2 nm, about 0.1 nm to about 1 nm, or about 0.1 nm to about 0.5 nm.

The intermediate insulating layer 107 may be formed after forming the channel layer 102 and before forming the gate insulating layer 105. For example, the intermediate insulating layer 107 may be formed at a deposition temperature of about 100° C. by using ALD. After the intermediate insulating layer 107 is formed, the gate insulating layer 105 may be formed on the intermediate insulating layer 107.

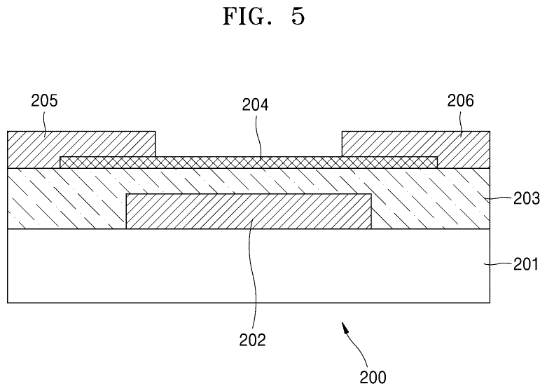

FIG. 5 is a cross-sectional view schematically illustrating a structure of a semiconductor device 200 according to at least one example embodiment. The semiconductor devices described above are the FET having the top gate structure in which the gate electrode is disposed at the upper side, but the disclosure is not necessarily limited thereto. For example, the semiconductor device may have a bottom gate structure in which the gate electrode is disposed at the lower side. Referring to FIG. 5, the semiconductor device 200 may include a substrate 201, a gate electrode 202 on the upper surface of the substrate 201, a gate insulating layer 203 on the upper surface of the gate electrode 202, a channel layer 204 on the upper surface of the gate insulating layer 203, and a source electrode 205 and a drain electrode 206 electrically connected to the channel layer 204. FIG. 5 illustrates that the gate insulating layer 203 extends from the upper surface of the gate electrode 202 through opposite side surfaces of the gate electrode 202 to opposite edges of the upper surface of the substrate 201 so as to surround opposite side surfaces of the gate electrode 202, but the disclosure is not necessarily limited thereto. For example, the gate insulating layer 203 may be provided only on the upper surface of the gate electrode 202. The material of the channel layer 204 may be the same as (or substantially similar to) the material of the channel layer 102 described with reference to FIG. 1; the material of the gate insulating layer 203 may be the same as (or substantially similar to) the material of the gate insulating layer 105 described with reference to FIG. 1; and the materials of the substrate 201, the source electrode 205, the drain electrode 206, and the gate electrode 202 may be the same as (or substantially similar to) the substrate 101, the source electrode 103, the drain electrode 104, and the gate electrode 106 described with reference FIG. 1.

In the bottom gate structure illustrated in FIG. 5, the source electrode 205 and the drain electrode 206 may be provided on opposite sides of the gate electrode 202 with respect to the gate insulating layer 203. For example, the source electrode 205 and the drain electrode 206 may be provided on the upper side of the gate insulating layer 203, and the gate electrode 202 may be provided on the lower side of the gate insulating layer 203. The source electrode 205 and the drain electrode 206 may be spaced apart from each other at opposite ends of the channel layer 204. In other words, the gate insulating layer 203 may include a first surface and a second surface facing each other, the source electrode 205 and the drain electrode 206 may be spaced apart from each other on the first surface of the gate insulating layer 203, and the gate electrode 202 may be disposed to face the second surface of the gate insulating layer 203.

FIG. 5 illustrates that the width of the channel layer 204 is less than the width of the gate insulating layer 203 and a portion of the source electrode 205 and the drain electrode 206 is in contact with the upper surface of the gate insulating layer 203, but the disclosure is not limited thereto. For example, the width of the channel layer 204 may be equal to the width of the gate insulating layer 203. In this case, the source electrode 205 and the drain electrode 206 may be spaced apart from each other on the upper surface of the channel layer 204.

In the case of the lower gate structure illustrated in FIG. 5, the gate electrode 202 may be first formed on the substrate 201. For example, the gate electrode 202 may be formed by depositing a conductive material on the substrate 201 and performing patterning thereon. After that, the gate insulating layer 203 may be formed on the substrate 201 to cover the gate electrode 202. Because the gate insulating layer 203 is formed before the channel layer 204, there is no risk of damage to the channel layer 204 while forming the gate insulating layer 203. In this case, the gate insulating layer 203 may be deposited at a temperature of about 200° C. by using ALD. After the gate insulating layer 203 is formed, the channel layer 204 may be formed on the gate insulating layer 203, and then, the source electrode 205 and the drain electrode 206 may be formed to be respectively electrically connected to opposite ends of the channel layer 204.

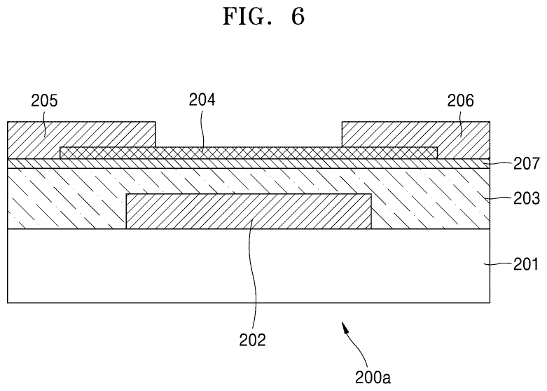

FIG. 6 is a cross-sectional view schematically illustrating a structure of a semiconductor device 200a according to at least one example embodiment. Referring to FIG. 6, the semiconductor device 200a may further include an intermediate insulating layer 207 between a gate insulating layer 203 and a channel layer 204. The remaining elements of the semiconductor device 200a illustrated in FIG. 6 may be the same as (or substantially similar to) those of the semiconductor device 200 illustrated in FIG. 5. The material of the intermediate insulating layer 207 may be the same as (or substantially similar to) the material of the intermediate insulating layer 107 described in FIG. 4.

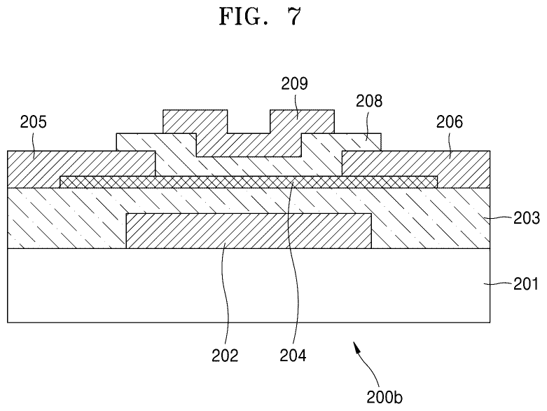

FIG. 7 is a cross-sectional view schematically illustrating a structure of a semiconductor device 200b according to at least one example embodiment. Referring to FIG. 7, the semiconductor device 200b may be an FET having a dual gate structure. Compared with the semiconductor device 200 illustrated in FIG. 5, the semiconductor device 200b illustrated in FIG. 7 may further include an upper gate insulating layer 208 between a source electrode 205 and a drain electrode 206 on an upper surface of a channel layer 204, and an upper gate electrode 209 on the upper gate insulating layer 208. In these cases, a gate electrode 202 under the channel layer 204 may be a ‘lower gate electrode’, and a gate insulating layer 203 under the channel layer 204 may be a ‘lower gate insulating layer’.

The upper gate insulating layer 208 may include the same material as (or substantially similar to) a material of the gate insulating layer 203. In other words, the upper gate insulating layer 208 may include Zr₍₁₋ₓ₎MₓO₂. The gate insulating layer 203 may have a tetragonal crystal structure, and the upper gate insulating layer 208 may have a tetragonal crystal structure or may be amorphous. Because the gate insulating layer 203 under the channel layer 204 already has a tetragonal crystal structure, the heat treatment may be omitted or may be performed at a temperature lower than 300° C. in the process of forming the upper gate insulating layer 208 on the channel layer 204, so as to protect against (e.g., prevent or reduce) damage to the channel layer 204. On the other hand, even in the semiconductor device 100 having the top gate structure illustrated in FIG. 1, the heat treatment may not be performed when there is a risk of damage to the channel layer 102 in the process of performing heat treatment on the gate insulating layer 105. In these cases, the gate insulating layer 105 of the semiconductor device 100 illustrated in FIG. 1 may be amorphous. Amorphous zirconium oxide may have a relatively high dielectric constant of about 22.

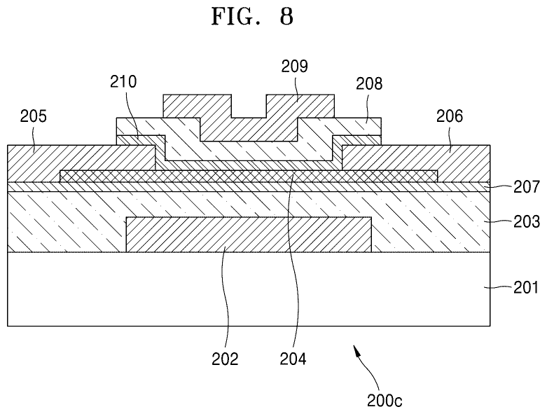

FIG. 8 is a cross-sectional view schematically illustrating a structure of a semiconductor device 200c according to at least one example embodiment. Referring to FIG. 8, the semiconductor device 200c may further include a lower intermediate insulating layer 207 between a channel layer 204 and a gate insulating layer 203 under the channel layer 204, and an upper intermediate insulating layer 210 between the channel layer 204 and an upper gate insulating layer 208 above the channel layer 204. The remaining elements of the semiconductor device 200c illustrated in FIG. 8 may be the same as (or substantially similar to) those of the semiconductor device 200b illustrated in FIG. 7. The materials of the lower intermediate insulating layer 207 and the upper intermediate insulating layer 210 may be the same as the material of the intermediate insulating layer 107 described with reference to FIG. 4.

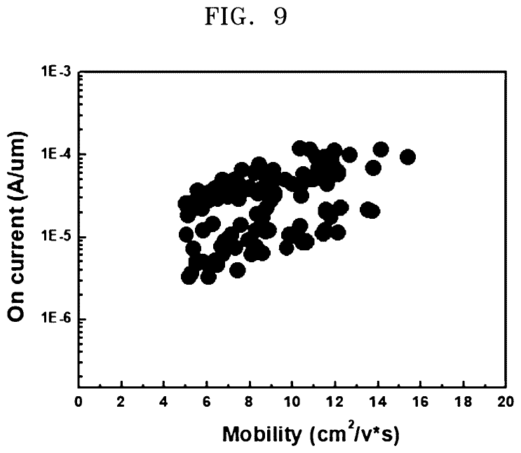

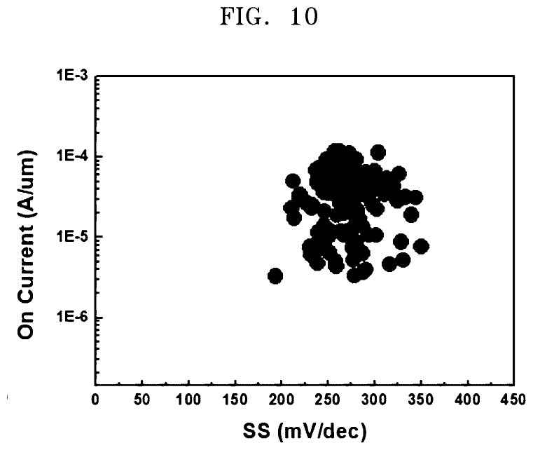

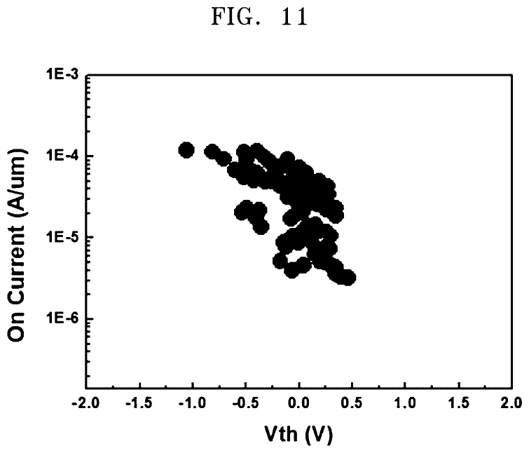

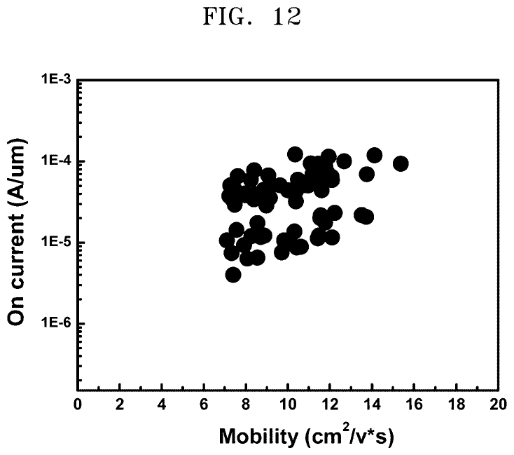

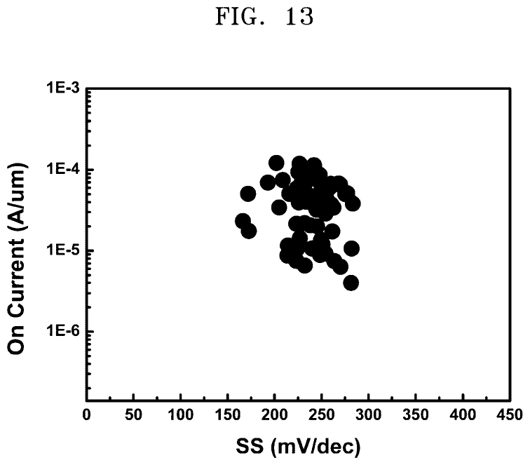

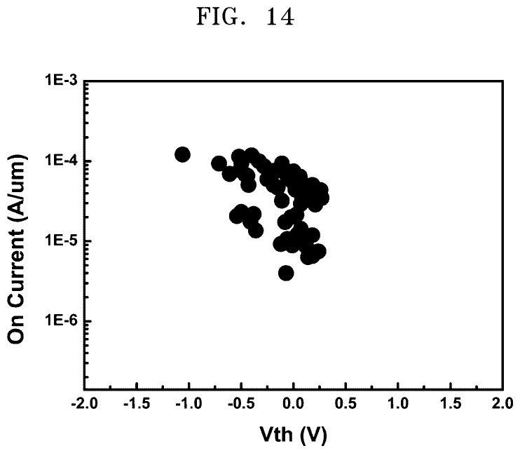

FIGS. 9 to 11 are graphs showing an example of various performances of the semiconductor device 200b illustrated in FIG. 7, and FIGS. 12 to 14 are graphs showing an example of various performances of the semiconductor device 200c illustrated in FIG. 8. In the graphs of FIGS. 9 to 14, the channel layer 204 used MoS₂, and the gate insulating layer 203 and the upper gate insulating layer 208 used 5 nm-thick Zr_{0.9}Hf_{0.1}O₂ having a tetragonal crystal structure. In the graphs of FIGS. 12 to 14, the lower intermediate insulating layer 207 and the upper intermediate insulating layer 210 used 0.2 nm-thick ZrO₂. FIGS. 9 and 12 show the results of measuring field effect (FE) mobility for a plurality of samples, FIGS. 10 and 13 show the results of measuring subthreshold swing (SS) for a plurality of samples, and FIGS. 11 and 14 show the results of measuring threshold voltage for a plurality of samples.

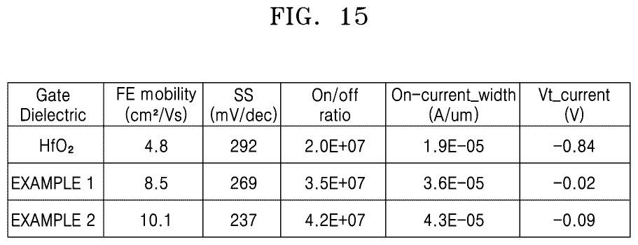

On the other hand, for comparison, a semiconductor device sample according to a comparative example was manufactured which did not include the lower intermediate insulating layer 207 and the upper intermediate insulating layer 210 and used 5 nm-thick HfO₂ as the gate insulating layer 203 and the upper gate insulating layer 208. FIG. 15 is a table showing an example of a comparison of various performances of the semiconductor devices according to the embodiments and various performances of a semiconductor device including a gate insulating layer using a material that is different from a material in the embodiments. In FIG. 15, Example 1 is organized by averaging the measurement results shown in FIGS. 9 to 11, and Example 2 is organized by averaging the measurement results shown in FIGS. 12 to 14.

Referring to the table of FIG. 15, it may be confirmed that Example 1 has a higher FE mobility than the comparative example, and Example 2 has a higher FE mobility than Example 1. In addition, SS is an amount of increase in a gate voltage applied to increase current in the channel by a factor of 10 at a subthreshold voltage. As the SS is smaller, the semiconductor device may be turned on/off more quickly. It may be confirmed that Example 1 has a smaller SS than the comparative example, and Example 2 has a smaller SS than Example 1. It may be confirmed that a ratio of on current to off current is greater in Example 1 than in the comparative example and is greater in Example 2 than in Example 1. It may also be confirmed that an amount of current flowing per unit width of the channel layer 204 in an on state is greater in Example 1 than in the comparative example and is greater in Example 2 than in Example 1. Vt is a voltage at which the current begins to increase in a quadratic function form when a gate voltage increases. Referring to the table of FIG. 15, it may be confirmed that Examples 1 and 2 have smaller Vt voltages than the comparative example. Therefore, it may be confirmed that the overall performance of the embodiments is improved.

A case where the semiconductor device is an FET having a planar channel has been described, but the disclosure is not necessarily limited thereto. For example, the technical aspect according to the embodiment described above may be applied to a FinFET, a gate-all-around FET (GAAFET), or a multi-bridge channel FET (MBCFET) having a three-dimensional channel structure.

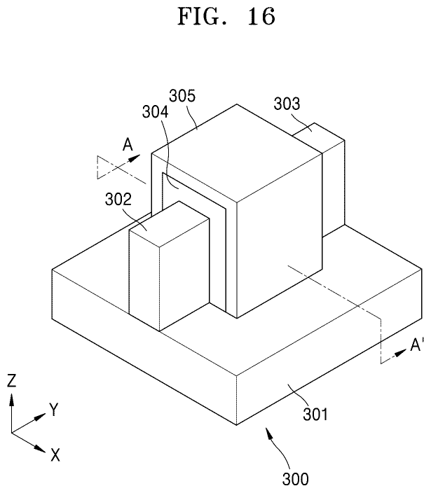

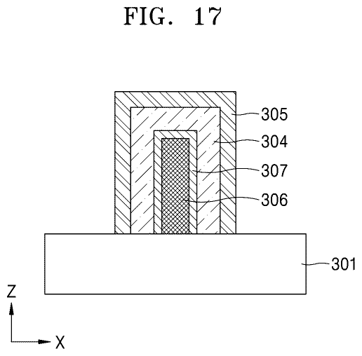

FIG. 16 is a perspective view schematically illustrating a structure of a semiconductor device 300 according to at least one example embodiment, and FIG. 17 is a cross-sectional view schematically illustrating a channel layer 307 and a gate electrode 305 of the semiconductor device 300 of FIG. 16 taken along line A-A′ of FIG. 16. The semiconductor device 300 illustrated in FIGS. 16 and 17 may be a FinFET. Referring to FIGS. 16 and 17, the semiconductor device 300 may include a substrate 301 having an insulating property, the channel layer 307 protruding from the substrate 301 in a first direction (a Z-axis direction), a gate insulating layer 304 surrounding opposite side surfaces of the channel layer 307 in a second direction (an X-axis direction) perpendicular to the first direction and the upper surface of the channel layer 307, the gate electrode 305 surrounding opposite side surfaces of the gate insulating layer 304 in the second direction and the upper surface of the gate insulating layer 304, a source electrode 302 protruding from the substrate 301 in the first direction and electrically connected to a first end portion of the channel layer 307 in a third direction (a Y-axis direction) perpendicular to the first and second directions, and a drain electrode 303 protruding from the substrate 301 in the first direction and electrically connected to a second end portion opposite to the first end portion of the channel layer 307 in the third direction. The materials of the channel layer 307, the gate insulating layer 304, the source electrode 302, the drain electrode 303, and the gate electrode 305 may be, respectively, the same as (or substantially similar to) the materials of the channel layer 102, the gate insulating layer 105, the source electrode 103, the drain electrode 104, and the gate electrode 106, described with reference to FIG. 1.

In addition, the semiconductor device 300 may further include a support 306 that supports the channel layer 307. The support 306 may protrude from the substrate 301 in the first direction. The channel layer 307 may surround three sides of the support 306. For example, the channel layer 307 may surround opposite side surfaces of the support 306 in the second direction (the X-axis direction) and the upper surface of the support 306. The support 306 may include, for example, one or more of an insulating material and/or a semiconductor material.

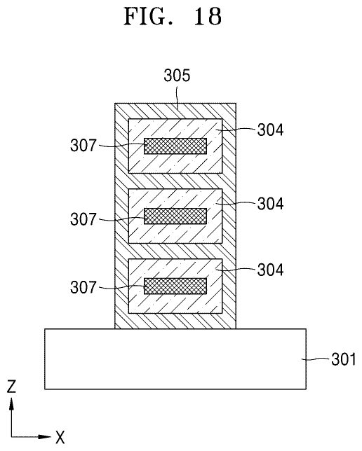

FIG. 18 is a cross-sectional view schematically illustrating a channel layer and a gate electrode of a semiconductor device according to at least one example embodiment. A structure of a source electrode and a drain electrode in the semiconductor device illustrated in FIG. 18 may be the same as the structure of the source electrode 302 and the drain electrode 303 described with reference to FIG. 16. FIG. 18 illustrates the structure of the channel layer and the gate electrode in the cross-section in the same direction as in FIG. 17. Referring to FIG. 18, the semiconductor device may include a plurality of channel layers 307 disposed at intervals from a substrate 301 along the first direction (the Z-axis direction). Although FIG. 18 illustrates three channel layers 307 as an example, the disclosure is not limited thereto and the semiconductor device may include more than three channel layers.

The semiconductor device may also include a plurality of gate insulating layers 304 surrounding opposite side surfaces of each of the plurality of channel layers 307 in the second direction (the X-axis direction) and the lower and upper surfaces of each of the plurality of channel layers 307, and a gate electrode 305 surrounding opposite side surfaces of each of the plurality of gate insulating layers 304 in the second direction and the lower and upper surfaces of each of the plurality of gate insulating layers 304. In other words, each of the plurality of gate insulating layers 304 may surround four sides of the corresponding channel layer among the plurality of channel layers 310. The gate electrode 305 may protrude from the substrate 301 in the first direction so as to surround four sides of each of the plurality of gate insulating layers 304. The plurality of gate insulating layers 304 may be disposed at intervals from the substrate 301 along the first direction, and the gate electrode 305 may be disposed between the plurality of gate insulating layers 304.

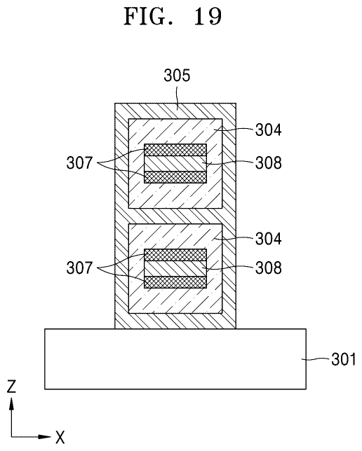

FIG. 19 is a cross-sectional view schematically illustrating a channel layer and a gate electrode of a semiconductor device according to at least one example embodiment. Referring to FIG. 19, two (or more) channel layers 307 may be surrounded by one gate insulating layer 304. In other words, the gate insulating layer 304 may surrounded two (or more) paired channel layer 307. Accordingly, the number of channel layers 307 may be twice the number of gate insulating layers 304. An insulator bridge 308 may be provided between the two channel layers 307 surrounded by the one gate insulating layer 304. The insulator bridge 308 may include an insulating material, and may electrically isolate the paired channel layers 307. Accordingly, the channel layer 307, the insulator bridge 308, and the channel layer 307 may be sequentially stacked along the first direction within the one gate insulating layer 304.

The semiconductor devices described above may be used in, for example, a driving integrated circuit of a display, a complementary metal-oxide semiconductor (CMOS) inverter, a CMOS SRAM device, a CMOS NOT-AND (CMOS NAND) circuit, a CMOS dynamic random access memory (DRAM), and/or various other electronic apparatuses.

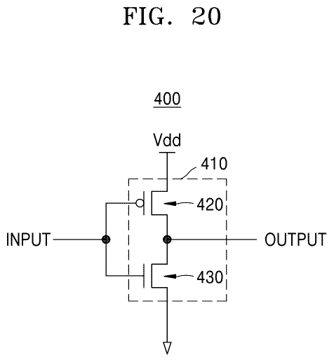

FIG. 20 is a circuit diagram of a CMOS inverter 400 according to at least one example embodiment. Referring to FIG. 20, the CMOS inverter 400 may include a CMOS transistor 410. The CMOS transistor 410 may include a p-channel metal-oxide semiconductor (PMOS) transistor 420 and an n-channel metal-oxide semiconductor (NMOS) transistor 430 connected between a power terminal Vdd and a ground terminal. The CMOS transistor 410 may include the semiconductor device according to the embodiments described above.

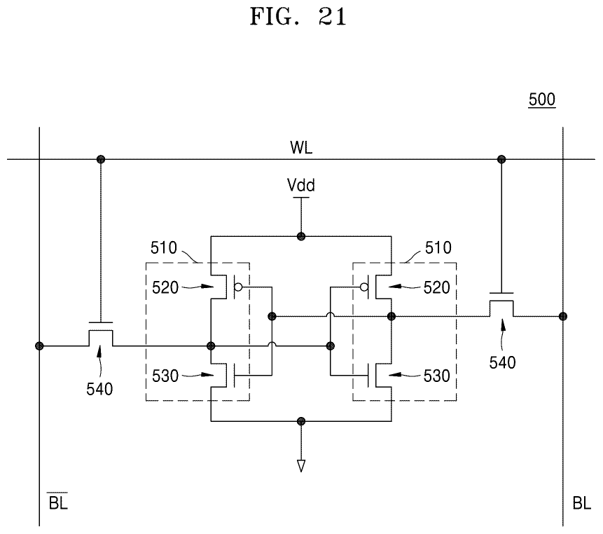

FIG. 21 is a circuit diagram of a CMOS SRAM device 500 according to at least one example embodiment. Referring to FIG. 21, the CMOS SRAM device 500 may include a pair of driving transistors 510. The pair of driving transistors 510 each includes a PMOS transistor 520 and an NMOS transistor 530 connected between a power terminal Vdd and a ground terminal. The CMOS SRAM device 500 may further include a pair of transmission transistors 540. A source of the transmission transistor 540 may be cross-connected to a common node of the PMOS transistor 520 and the NMOS transistor 530 constituting the driving transistor 510. The power terminal Vdd may be connected to a source of the PMOS transistor 520, and the ground terminal may be connected to a source of the NMOS transistor 530. A word line WL may be connected to a gate of the pair of transmission transistors 540, and a bit line BL and an inverted bit line may be connected to a drain of each of the pair of transmission transistors 540, respectively. At least one of the driving transistor 510 or the transmission transistor 540 of the CMOS SRAM device 500 may include the semiconductor device according to the example embodiments described above.

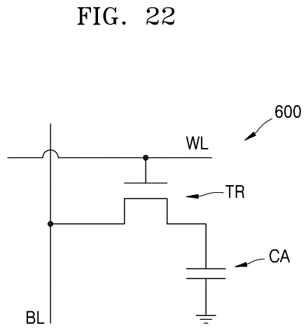

FIG. 22 is a circuit diagram of a CMOS DRAM device 600 according to at least one example embodiment. Referring to FIG. 22, the CMOS DRAM device 600 may include one transistor TR, one capacitor CA, a word line WL, and a bit line BL. The word line WL may be electrically connected to a gate of the transistor TR, and the bit line BL may be electrically connected to a source of the transistor TR. A first electrode of the capacitor CA may be connected to a drain of the transistor TR, and a second electrode of the capacitor CA may be grounded. The transistor TR of the CMOS DRAM device 600 may include the semiconductor device according to the example embodiments described above.

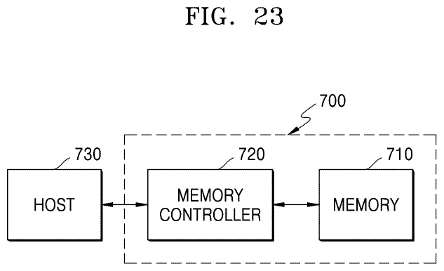

FIG. 23 is a block diagram illustrating an electronic apparatus 700 according to at least one example embodiment. Referring to FIG. 23, the electronic apparatus 700 may include a memory 710 and a memory controller 720. The memory controller 720 may control the memory 710 to read data from and/or write data into the memory 710 in response to a request from the host 730. At least one of the memory 710 or the memory controller 720 may include the semiconductor device according to the example embodiments described above with reference to FIGS. 1 to 19.

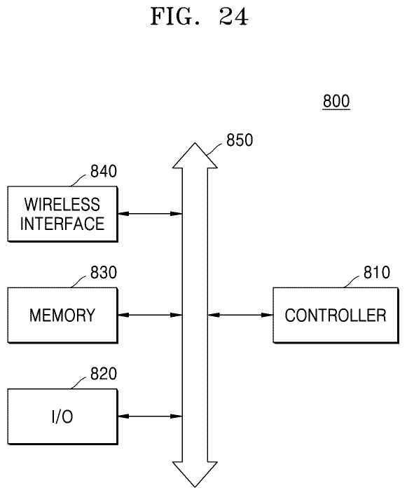

FIG. 24 is a block diagram of an electronic apparatus 800 according to at least one example embodiment. Referring to FIG. 24, the electronic apparatus 800 may constitute a wireless communication device or a device capable of transmitting and/or receiving information in a wireless environment. The electronic apparatus 800 may include a controller 810, an input/output (I/O) device 820, a memory 830, and a wireless interface 840, and these components are interconnected to each other through a bus 850.

The controller 810 may include at least one of a microprocessor, a digital signal processor, or a processing device similar thereto. The I/O device 820 may include at least one of a keypad, a keyboard, or a display. The memory 830 may be used to store instructions executed by controller 810. For example, the memory 830 may be used to store user data. The electronic apparatus 800 may use the wireless interface 840 to transmit/receive data through a wireless communication network. The wireless interface 840 may include an antenna and/or a wireless transceiver. In some embodiments, the electronic apparatus 800 may be used in a communication interface protocol of a third-generation communication system, for example, code division multiple access (CDMA), global system for mobile communications (GSM), north American digital cellular (NADC), extended-time division multiple access (E-TDMA), and/or wide band code division multiple access (WCDMA). The electronic apparatus 800 may include the semiconductor device according to the embodiments described above.

The embodiments described above may be summarized as follows.
(1) A semiconductor device according to at least one example embodiment may include a channel layer comprising a semiconductor material having a two-dimensional crystal structure, a source electrode electrically connected to the channel layer, a drain electrode electrically connected to the channel layer, a gate electrode facing the channel layer, and a gate insulating layer between the channel layer and the gate electrode, the gate insulating layer may include a three-dimensional bulk paraelectric material including zirconium oxide and an oxide of a metal having a valence of +3 or +4.
(2) For example, the gate insulating layer may include Zr₍₁₋ₓ₎MₓO₂, wherein the M may represent the metal having the valence of +3 or +4.
(3) The M may include, for example, at least one of yttrium (Y), aluminum (Al), gallium (Ga), indium (In), silicon (Si), germanium (Ge), titanium (Ti), hafnium (Hf), tin (Sn), or a combination thereof.
(4) In some examples, the x may be 0.01 to 0.3.
(5) In some examples, the x may be 0.01 to 0.2.
(6) The gate insulating layer may have a tetragonal crystal structure.
(7) A thickness of the gate insulating layer may be 2 nm to 10 nm.
(8) The semiconductor device may further include an intermediate insulating layer between the channel layer and the gate insulating layer, wherein the intermediate insulating layer may include at least one three-dimensional bulk paraelectric material, the at least one three-dimensional bulk paraelectric material including one or more of zirconium oxide, silicon oxide, titanium oxide, yttrium oxide, germanium oxide, tin oxide, aluminum oxide, indium oxide, hafnium oxide, gallium oxide, or a combination thereof.
(9) A thickness of the intermediate insulating layer may be 0.1 nm to 2 nm.
(10) The semiconductor material having the two-dimensional crystal structure may include a transition metal dichalcogenide material.
(11) The semiconductor device may further include a substrate, wherein the channel layer may be on the substrate, the source electrode and the drain electrode may be respectively electrically connected to opposite ends of the channel layer, the gate insulating layer may be on the channel layer, and the gate electrode may be on the gate insulating layer.
(12) The gate insulating layer may have at least one of a tetragonal crystal structure or an amorphous structure.
(13) The gate insulating layer may be on an upper surface of the gate electrode, the channel layer may be on the gate insulating layer, and the source electrode and the drain electrode may be on the gate insulating layer and respectively electrically connected to opposite ends of the channel layer.
(14) The semiconductor device may further include an upper gate insulating layer above the channel layer and an upper gate electrode above the upper gate insulating layer.
(15) The gate insulating layer may have a tetragonal crystal structure, and the upper gate insulating layer may have at least one of a tetragonal crystal structure or an amorphous structure.
(16) The semiconductor device may further include a substrate, wherein the channel layer may protrude from the substrate in a first direction, the gate insulating layer may surround opposite side surfaces of the channel layer in a second direction perpendicular to the first direction and an upper surface of the channel layer, and the gate electrode may surround opposite side surfaces of the gate insulating layer in a second direction and an upper surface of the gate insulating layer.
(17) The semiconductor device may further include a substrate, wherein the channel layer may include a plurality of channel layers disposed at intervals from the substrate along a first direction, the gate insulating layer may include a plurality of gate insulating layers surrounding opposite side surfaces of each of the plurality of channel layers in a second direction perpendicular to the first direction and a lower surface and an upper surface of each of the plurality of channel layers, and the gate electrode may protrude from the substrate in the first direction so as to surround the plurality of gate insulating layers.
(18) Two channel layers may be surrounded by one gate insulating layer, and the semiconductor device may further include an insulator bridge between the two channel layers surrounded by the one gate insulating layer.
(19) A method of manufacturing a semiconductor device, according to at least one example embodiment, may include forming a channel layer including a semiconductor material having a two-dimensional crystal structure, forming a source electrode and a drain electrode so that the source electrode and the source drain are electrically connected to the channel layer, forming a gate insulating layer so that the gate insulating layer faces the channel layer, the gate insulating layer including a three-dimensional bulk paraelectric material including zirconium oxide and an oxide of a metal having a valence of +3 or +4, and forming a gate electrode on an area of the gate insulating layer such that the gate insulating layer is between the gate electrode and the channel layer, wherein the forming of the gate insulating layer may include depositing the gate insulating layer by using atomic layer deposition and heat treating the deposited gate insulating layer at a temperature of 300° C. for 10 minutes or at a temperature of 400° C. for about 1 minute.
(20) The depositing of the gate insulating layer may include depositing Zr₍₁₋ₓ₎MₓO₂ at a temperature of 150° C. to 200° C., and the M representing the metal having the valence of +3 or +4 and may include at least one of yttrium (Y), aluminum (Al), gallium (Ga), indium (In), silicon (Si), germanium (Ge), titanium (Ti), hafnium (Hf), tin (Sn), or a combination thereof.
(21) The forming of the gate insulating layer may further include forming an intermediate insulating layer on the channel layer before the depositing of the gate insulating layer, and the intermediate insulating layer may include at least one three-dimensional bulk paraelectric material selected from zirconium oxide, silicon oxide, titanium oxide, yttrium oxide, germanium oxide, tin oxide, aluminum oxide, indium oxide, hafnium oxide, gallium oxide, or a combination thereof.
(22) A method of manufacturing a semiconductor device, according to at least one example embodiment, may include forming a gate electrode on a substrate, forming a gate insulating layer on the substrate so as to cover the gate electrode, forming a channel layer on the gate insulating layer, the channel layer including a semiconductor material having a two-dimensional crystal structure, and forming a source electrode and a drain electrode electrically connected to the channel layer, wherein the forming of the gate insulating layer may include depositing the gate insulating layer using atomic layer deposition and performing heat treatment on the deposited gate insulating layer at a temperature of 300° C. for 10 minutes or at a temperature of 400° C. for about 1 minute.
(23) The depositing of the gate insulating layer may include depositing Zr₍₁₋ₓ₎MₓO₂ at a temperature of 200° C., and the M representing the metal having the valence of +3 or +4 and may include at least one metal selected from yttrium (Y), aluminum (Al), gallium (Ga), indium (In), silicon (Si), germanium (Ge), titanium (Ti), hafnium (Hf), tin (Sn), or a combination thereof.
(24) The method may further include forming an upper gate insulating layer between the source electrode and the drain electrode on the channel layer and forming an upper gate electrode on the upper gate insulating layer.
(25) The forming of the upper gate insulating layer may include depositing Zr₍₁₋ₓ₎MₓO₂ at a temperature of 150° C., and the M may include at least one of yttrium (Y), aluminum (Al), gallium (Ga), indium (In), silicon (Si), germanium (Ge), titanium (Ti), hafnium (Hf), or tin (Sn).
(26) The forming of the upper gate insulating layer may further include performing a heat treatment at a temperature of 300° C. for 10 minutes or at a temperature of 400° C. for about 1 minute.
(27) The method may further include forming an intermediate insulating layer on the gate insulating layer before the forming of the channel layer, and the intermediate insulating layer may include at least one three-dimensional bulk paraelectric material selected from zirconium oxide, silicon oxide, titanium oxide, yttrium oxide, germanium oxide, tin oxide, aluminum oxide, indium oxide, hafnium oxide, gallium oxide, or a combination thereof.
(28) A method of manufacturing a semiconductor device may include forming a channel layer including a semiconductor material having a two-dimensional crystal structure, forming a source electrode and a drain electrode so that the source electrode and the drain electrode are electrically connected to the channel layer, forming a gate insulating layer on the channel layer, the gate insulating layer including a three-dimensional bulk paraelectric material including zirconium oxide and an oxide of a metal having a valence of +3 or +4, and forming a gate electrode on an area of the gate insulating layer so that the gate insulating layer is between the gate electrode and the channel layer, wherein the forming of the gate insulating layer may include depositing the gate insulating layer using atomic layer deposition and heat treating the deposited gate insulating layer at a temperature of 300° C. for 10 minutes or at a temperature of 400° C. for about 1 minute.
(29) An electronic apparatus according to at least one example embodiment may include a transistor, a word line electrically connected to a gate of the transistor, a bit line electrically connected to a source of the transistor, and a capacitor electrically connected to a drain of the transistor, wherein the transistor may include a channel layer comprises a semiconductor material having a two-dimensional crystal structure, a source electrode electrically connected to the channel layer, a drain electrode electrically connected to the channel layer, a gate electrode facing the channel layer, and a gate insulating layer between the channel layer and the gate electrode, and the gate insulating layer may include a three-dimensional bulk paraelectric material including zirconium oxide and an oxide of a metal having a valence of +3 or +4.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer comprising a semiconductor material having a two-dimensional crystal structure;
a source electrode electrically connected to the channel layer;
a drain electrode electrically connected to the channel layer;
a gate electrode facing the channel layer; and
a gate insulating layer between the channel layer and the gate electrode, the gate insulating layer comprises a three-dimensional bulk paraelectric material comprising zirconium oxide and an oxide of a metal having a valence of +3 or +4.

2. The semiconductor device of claim 1, wherein the gate insulating layer comprises Zr₍₁₋ₓ₎MₓO₂, wherein the M is the metal having the valence of +3 or +4.

3. The semiconductor device of claim 2, wherein the M comprises at least one of yttrium (Y), aluminum (Al), gallium (Ga), indium (In), silicon (Si), germanium (Ge), titanium (Ti), hafnium (Hf), tin (Sn), or a combination thereof.

4. The semiconductor device of claim 2, wherein the x is 0.01 to 0.3.

5. The semiconductor device of claim 2, wherein the x is 0.01 to 0.2.

6. The semiconductor device of claim 1, wherein the gate insulating layer has a tetragonal crystal structure.

7. The semiconductor device of claim 1, wherein a thickness of the gate insulating layer is 2 nanometers (nm) to 10 nm.

8. The semiconductor device of claim 1, further comprising:
an intermediate insulating layer between the channel layer and the gate insulating layer,
wherein the intermediate insulating layer comprises at least one three-dimensional bulk paraelectric material, the at least one three-dimensional bulk paraelectric material including zirconium oxide, silicon oxide, titanium oxide, yttrium oxide, germanium oxide, tin oxide, aluminum oxide, indium oxide, hafnium oxide, gallium oxide, or a combination thereof.

9. The semiconductor device of claim 8, wherein a thickness of the intermediate insulating layer is 0.1 nanometers (nm) to 2 nm.

10. The semiconductor device of claim 1, wherein the semiconductor material having the two-dimensional crystal structure comprises a transition metal dichalcogenide material.

11. The semiconductor device of claim 1, further comprising:
a substrate,
wherein the channel layer is on the substrate,
the source electrode and the drain electrode are respectively electrically connected to opposite ends of the channel layer,
the gate insulating layer is on the channel layer, and
the gate electrode is on the gate insulating layer.

12. The semiconductor device of claim 11, wherein the gate insulating layer has at least one of a tetragonal crystal structure or an amorphous structure.

13. The semiconductor device of claim 1, wherein the gate insulating layer is on an upper surface of the gate electrode,
the channel layer is above the gate insulating layer, and
the source electrode and the drain electrode are above the gate insulating layer and respectively electrically connected to opposite ends of the channel layer.

14. The semiconductor device of claim 13, further comprising:
an upper gate insulating layer above the channel layer; and
an upper gate electrode above the upper gate insulating layer.

15. The semiconductor device of claim 14, wherein the gate insulating layer has a tetragonal crystal structure, and the upper gate insulating layer has at least one of a tetragonal crystal structure or an amorphous structure.

16. The semiconductor device of claim 1, further comprising:
a substrate,
wherein the channel layer protrudes from the substrate in a first direction,
the gate insulating layer surrounds an upper surface of the channel layer and opposite side surfaces of the channel layer in a second direction perpendicular to the first direction, and
the gate electrode surrounds an upper surface of the gate insulating layer and opposite side surfaces of the gate insulating layer in the second direction.

17. The semiconductor device of claim 1, further comprising:
a substrate,
wherein the channel layer comprises a plurality of channel layers disposed at intervals from the substrate along a first direction,
the gate insulating layer comprises a plurality of gate insulating layers surrounding a lower surface and an upper surface of each of the plurality of channel layers and opposite side surfaces of each of the plurality of channel layers in a second direction perpendicular to the first direction, and
the gate electrode protrudes from the substrate in the first direction so as to surround the plurality of gate insulating layers.

18. A method of manufacturing a semiconductor device, the method comprising:
forming a channel layer comprising a semiconductor material having a two-dimensional crystal structure;
forming a source electrode and a drain electrode so that the source electrode and the drain electrode are electrically connected to the channel layer;
forming a gate insulating layer so that the gate insulating layer faces the channel layer, the gate insulating layer comprising a three-dimensional bulk paraelectric material comprising zirconium oxide and an oxide of a metal having a valence of +3 or +4; and
forming a gate electrode on an area of the gate insulating layer such that the gate insulating layer is between the gate electrode and the channel layer,
wherein the forming of the gate insulating layer comprises:
depositing the gate insulating layer using atomic layer deposition, and
heat treating the deposited gate insulating layer at a temperature of 300 degrees Celsius (°C) for 10 minutes or at a temperature of 400° C. for about 1 minute.

19. The method of claim 18, wherein the depositing of the gate insulating layer comprises depositing Zr₍₁₋ₓ₎MₓO₂ at a temperature of 150° C. to 200° C., and
the M representing the metal having the valence of +3 or +4 and including at least of yttrium (Y), aluminum (Al), gallium (Ga), indium (In), silicon (Si), germanium (Ge), titanium (Ti), hafnium (Hf), tin (Sn), or a combination thereof.

20. An electronic apparatus comprising:
a transistor;
a word line electrically connected to a gate of the transistor;
a bit line electrically connected to a source of the transistor; and
a capacitor electrically connected to a drain of the transistor,
wherein the transistor comprises
a channel layer comprises a semiconductor material having a two-dimensional crystal structure,
a source electrode electrically connected to the channel layer,
a drain electrode electrically connected to the channel layer,
a gate electrode facing the channel layer, and
a gate insulating layer between the channel layer and the gate electrode, the gate insulating layer comprises a three-dimensional bulk paraelectric material comprising zirconium oxide and an oxide of a metal having a valence of +3 or +4.
